(19) United States
(12) Patent Application Publication
(10) Pub. No.: US 2003/0159819 A1
(43) Pub. Date: Aug. 28, 2003

(54) Heatsink device for cooling chipset

(76) Inventor: Sang-Cheol Lee, Kyungki-do (KR)

Correspondence Address: ST. ONGE STEWARD JOHNSTON & REENS, LLC, 986 BEDFORD STREET, STAMFORD, CT, 06905-5619, US

(21) Appl. No.: 10/374,856

(22) Filed: Feb. 26, 2003

(30) Foreign Application Priority Data
Feb. 27, 2002 (KR) 2002-10663

(51) Int. Cl. F28F 7/00; H05K 7/20; H01L 23/34

(52) U.S. Cl. 165/185; 165/80.3; 361/704; 257/719

(57) ABSTRACT

A heatsink device for cooling a chipset is provided. The heatsink device for cooling a chipset mounted on a printed circuit board to interface a central processing unit with a peripheral device, the printed circuit board including a plurality of installation holes near the chipset, the heatsink device including: a heatsink mounted to contact the top surface of the chipset to externally dissipate heat generated by the chipset, the heatsink having a pair of parallel guide grooves at the bottom edge regions which do not contact the chipset; and an installation unit which is fixed to be movable in each of the guide grooves and is connected to one installation hole of the printed circuit board, to bring the heatsink in contact with the top surface of the heatsink. The installation unit, which binds the heatsink to a chipset, is fixed to a bottom edge region to be movable along the bottom edge of the heatsink, so that the heatsink can be mounted on any printed circuit board having installation holes at a variety of different positions by adjusting the position of the installation unit to the position of the corresponding installation hole. The installation unit includes a spring to elastically push the heatsink toward the chipset and to absorb external vibrations or impacts, so that the chipset can be protected from external vibrations or impacts.

### FIELD OF THE INVENTION

The present invention relates to a heatsink device, and more particularly, to a heatsink device for cooling a chipset connecting a central processing unit (CPU) to a peripheral device.

### BACKGROUND OF THE INVENTION

This application claims priority from Korean Patent Application No. 2002-10663, filed on Feb. 27, 2002, in the Korean Intellectual Property Office, the disclosure of which is incorporated herein in its entirety by reference.

Various electronic parts are mounted on a main board in a computer case. These electronic parts mounted on the main board include a central processing unit (CPU) and a chipset connecting the CPU and a peripheral device. As is well known, since the CPU and chipset generate a large amount of heat during operation, heatsinks need to be mounted thereon to prevent overheating.

Such heatsinks basically have a heat-absorbing portion and a heat-dissipating portion to absorb heat generated by a heat-generating source and to dissipate the absorbed heat. Various kinds of heatsinks are available.

FIG. 1 is a perspective view of a conventional heatsink for cooling a chipset. As shown in FIG. 1, a conventional heatsink 10 includes a heat-absorbing portion 16 with installation parts 14 at its corners, which is mounted to contact the top surface of a chipset mounted on a printed circuit board (C), and a heat-dissipating portion 18 that extends from the heat-absorbing portion 16 upward to transfer heat absorbed by the heat-absorbing portion 16 to the air. The heat-dissipating portion 18 includes a plurality of heat dissipating fins.

In FIG. 1, reference numeral 24 denotes an installation hole formed through the printed circuit board C. In general, two installation holes are formed near the chipset A. However, the position of these installation holes 24 varies in different types of printed circuit boards.

The installation parts 14, which are formed at diagonally opposing corners, with the heat-absorbing portion 16 of the heatsink 10 therebetween, have holes 20. After matching the holes 20 with the installation holes 24, the bolts 22 are inserted through the holes 20 and screwed into the installation holes 24, so that the heatsink 10 is bound to the printed circuit board C to contact the top surface of the chipset.

However, since the installation parts 14 are fixed to the heatsink 10, the relative position of the hole 20 to the heatsink 10 cannot be adjusted. Therefore, the heatsink 10 cannot be mounted on a printed circuit board C having installation holes that do not match with the holes 20.

When the holes 20 of the heatsink 10 do not match with the installation holes 24, the heatsink 10 may be mounted on the printed circuit board C by making new installation holes that matches the holes 20. However, most printed circuit boards are densely populated with various kinds of parts or circuits, so that these circuits may be damaged when forming a new installation hole. Therefore, this method is impractical.

Another approach is to use adhesive, instead of forming new installation holes, to fix a heatsink to a chipset. In this method, an adhesive is applied to the top surface of the chipset and the bottom of the heatsink, the chipset and the heatsink are pushed toward each other such that the bottom of the heatsink is adhered to the chipset.

However, the adhesive used in this method does not have high heat transfer efficiency. A larger amount of heat being transferred to a heatsink after being emitted from a chipset leads to higher heat dissipating efficiency. However, if heat transfer from the chipset to the heatsink is hindered by the adhesive, the chipset cannot be effectively cooled.

Moreover, since the adhesive tightly fixes the heatsink to the chipset, it is practically impossible to separate the heatsink from the chipset when required. If the heatsink is pulled to separate it from the chipset to reinstall or replace, the chipset is torn from the printed circuit board, thereby causing the chipset as well as the printed circuit board to break. It is impractical to separate the heatsink from the chipset using any methods other than the physical method.

### SUMMARY OF THE INVENTION

The present invention provides a heatsink device for cooling a chipset, which has an installation unit installed at its bottom edge region to be movable along the bottom edge of the heatsink, to bind the heatsink to a printed circuit board. With this installation unit, the heatsink can be mounted printed circuit boards having installation holes at a variety of different positions by adjusting the position of the installation unit to match the position of the corresponding installation hole. In the heatsink device according to the present invention, the installation unit includes a spring to elastically push the heatsink against to the chipset and to absorb external vibrations or impacts, so that the chipset can be protected from external vibrations or impacts.

According to an aspect of the present invention, there is provided a heatsink device for cooling a chipset mounted on a printed circuit board to interface a central processing unit with a peripheral device, the printed circuit board including a plurality of installation holes near the chipset, the heatsink device comprising: a heatsink mounted to contact the top surface of the chipset to externally dissipate heat generated by the chipset, the heatsink having a pair of parallel guide grooves at the bottom edge regions which do not contact the chipset; and an installation unit which is fixed to be movable in each of the guide grooves and is connected to one installation hole of the printed circuit board, to bring the heatsink in contact with the top surface of the heatsink.

In another heatsink device according to the present invention, the installation unit may comprises: a planar link of a predetermined width and length and having a slit extending in a lengthwise direction; a fixing pin inserted into the slit of the planar link and having a head and a flanged conical end which is inserted through an installation hole of the printed circuit board and supports the printed circuit board upward by the flanged conical end; a spring slid over the fixing pin to elastically support the head of the fixing pin in the vertical direction while being supported by the rim of the slit of the planar link; and a link fixing element which fixes one end of the planar link at a desired position in each of the guide grooves.

The link fixing element may comprise a bolt passed through the planar link; and a nut coupled to the bolt. Each of the guide grooves has a space with a recess fit to support the nut. While the nut is loosely joined with the bolt and inserted into the space, the bolt is tightened up with respect to the nut such that the planar link is supported by a head of the bolt, so that the planar link is fixed to the heatsink.

According to the present invention, the width and cross section of each of the guide grooves is consistent along the entire length of the guide grooves.

### BRIEF DESCRIPTION OF THE DRAWINGS

The above and other features and advantages of the present invention will become more apparent by describing in detail exemplary embodiments thereof with reference to the attached drawings in which:

FIG. 1 is a perspective view of a conventional heatsink for cooling a chipset;

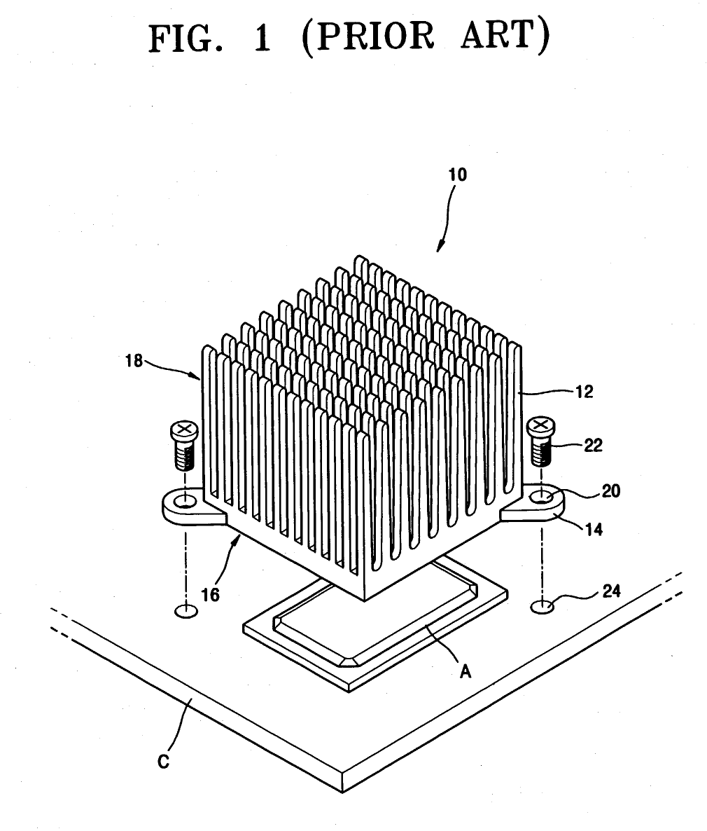

FIG. 2 is a partially exploded perspective view of a heatsink device for cooling a chipset according to an embodiment of the present invention;

FIG. 3 illustrates a mechanism which binds an installation unit to a heatsink in the heatsink device according to the embodiment of the present invention;

FIG. 4 is an inverted perspective view of the heatsink device according to the embodiment of the present invention;

FIG. 5 illustrates the installation of the heatsink device for cooling a chipset according to the embodiment of the present invention on a printed circuit board; and

FIG. 6 is a sectional view of the heatsink device according to the embodiment of the present invention mounted on the printed circuit board.

### DETAILED DESCRIPTION OF THE DRAWINGS

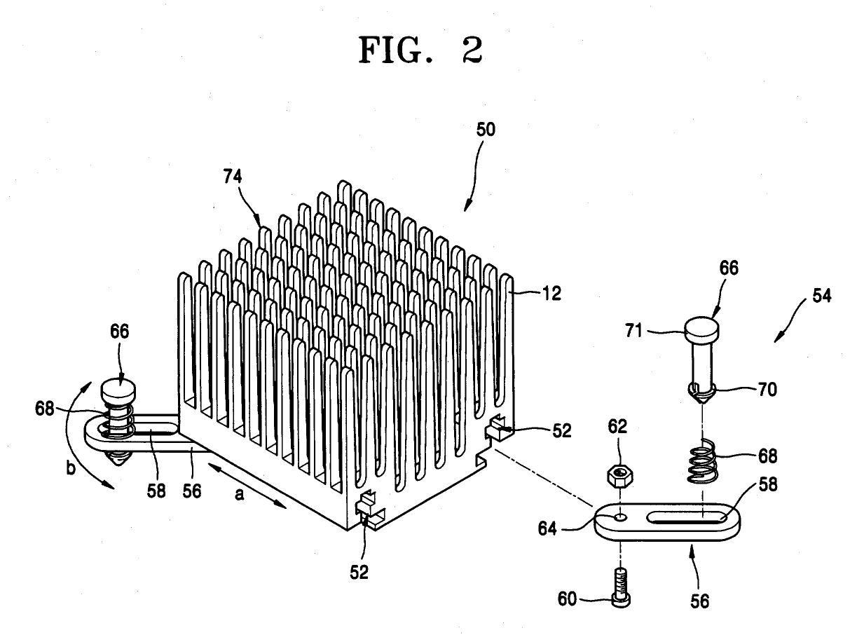

Embodiments of the present invention will be described in greater detail with reference to the appended drawings. FIG. 2 is a partially exploded perspective view of a heatsink device for cooling a chipset according to an embodiment of the present invention.

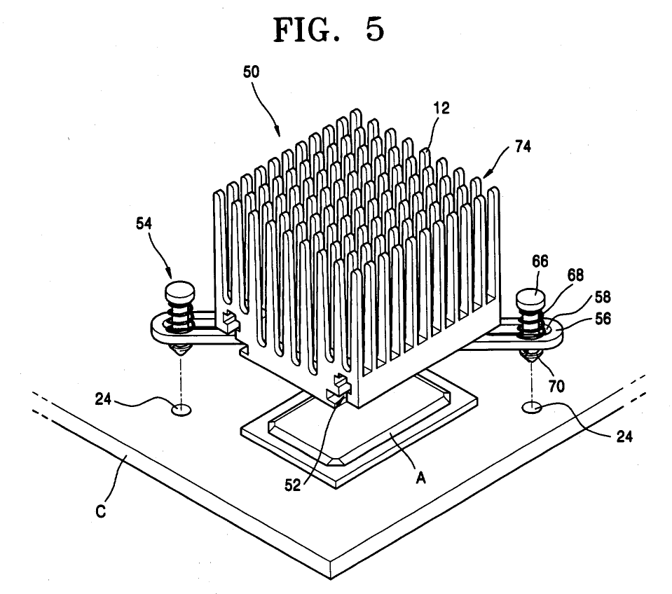

Referring to FIG. 2, a heatsink device 50 for cooling a chipset according to an embodiment of the present invention includes a heatsink 74 mounted on the top surface of a chipset A (see FIG. 5), the heatsink 74 having two guide grooves 52 formed at the bottom edges thereof, and installation units 54 inserted into the guide grooves 52 of the heatsink 74 and bound to a printed circuit board C (see FIG. 5).

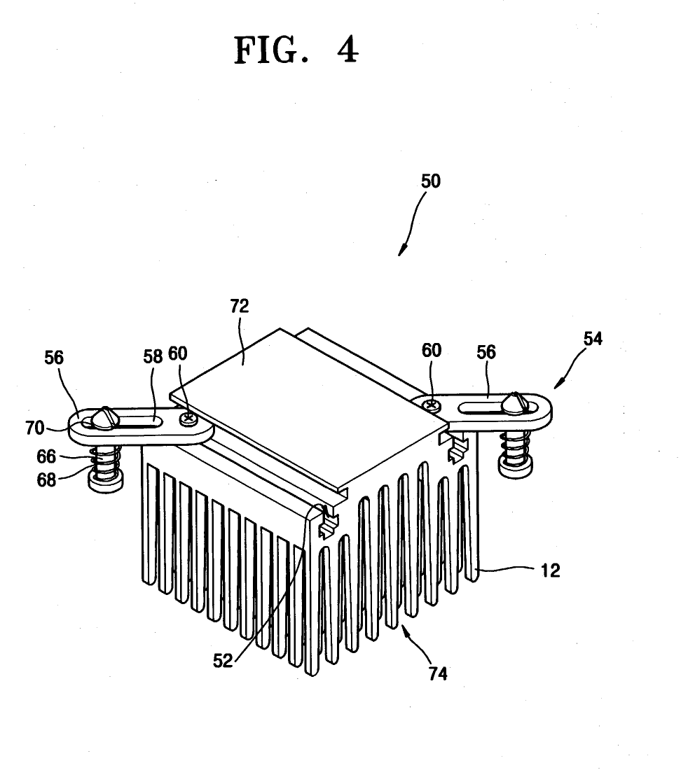

Like known heatsinks, the heatsink 74 has a plurality of heat dissipating fins 12 to emit heat generated by the chipset into the air. The center of the bottom of the heatsink 74 is processed to be flat, as shown in FIG. 4, to ensure flash contact with the entire top surface of the chipset.

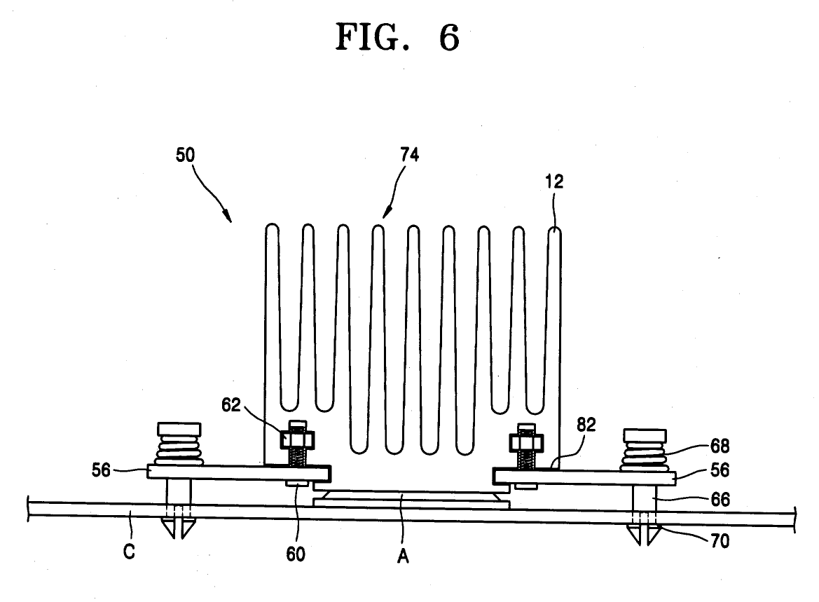

The guide grooves 52 are formed at opposing bottom edge regions of the heatsink 74 parallel to each other and symmetrical with respect to the chipset A placed underneath the heatsink 74, as shown in FIG. 6. The width and cross section of each of the guide grooves 52 is consistent along the entire length of the guide groove 52.

Each of the installation units 54 has a planar link 56 having a slit 58 and a hole 64, a fixing pin 66 inserted through the slit 58 of the planar link 56, a spring 68 which elastically supports the fixing pin 66 in the vertical direction with respect to the slit 58, and a bolt 60 and a nut 62 which couple to each other via the hole 64. The planar link 56 is a bar-like member having a constant width and thickness.

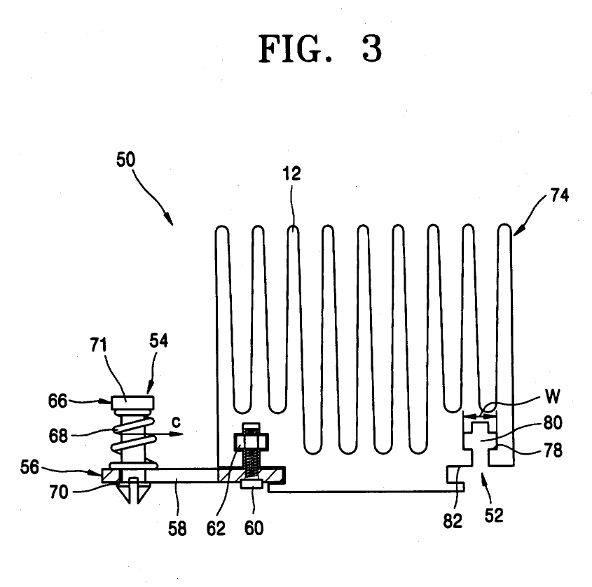

As described later, the bolt 60 inserted through the hole 64 acts as a pivot shaft of the planer rod 56. The bolt 60 is inserted through the hole 64 to couple to the nut 62. Then, while the nut 62 and the bolt 60 are not tightly joined together, the nut 62 is slid into a space 80 (see FIG. 3) of the guide groove 52 so that the end of the planar link 56 opposite to the hole 64 extends outward from the heatsink 74.

It will be appreciated that the nut 62 placed in the space 80 can be rectilinearly moved along the lengthwise direction of the guide groove 52. As described later, when the nut 62 is slid into the space 80 and tightly coupled with the bolt 60, the planar link 56 is supported with respect to the bottom surface of the heatsink 74 and prevented from moving by the head of the bolt 60. As the bolt 60 is tightened into the nut 62, the planar link 56 is more stably fixed to the heatsink 74.

As is widely known, the fixing pin 66 inserted through the slit 58 has a head 71 and a flanged conical end 70. The flanged conical end 70 has a larger diameter region than the region between the flanged conical end 70 and the head 71. The center region of the flanged conical end 70 is vertically cut out such that the flanged conical end 70 can be flexibly pushed inside the slit 58 and spring open and engage the rim at the bottom of the slit 58. Therefore, as shown in FIG. 6, the planar link 56 can be coupled to the printed circuit board C by pushing the fixing pin 66 through the installation hole 24 (see FIG. 5) formed in the printed circuit board C.

The spring 68 elastically supports the fixing pin 66 in the vertical direction with respect to the planar link 56. The spring 68 is slid over the fixing pin 66, and the fixing pin 66 having the spring 68 on it is inserted into the slit 58 of the planar link 56 such that the head 71 of the fixing pin 66 is elastically supported in the vertical direction by the spring 68 supported by the slit 58. Although the fixing pin 66 is elastically pushed upward by the spring 68, the fixing pin 66 can be caught in the slit 58 since the flanged conical end 70 is engaged with the rim of the slit 58 at the opposite side.

The installation unit 54 that has been completely assembled is movable rectilinearly in the directions indicated by arrow a and is pivotable about the bolt 60 in the directions indicated by arrow b. Therefore, even through the position of installation holes formed near a chipset varies for different printed circuit boards, the heatsink according to the present invention can be mounted on any printed circuit board by changing the position of the installation unit 54.

FIG. 3 illustrates the mechanism of binding the installation unit to the heatsink in the heatsink device according to the above embodiment of the present invention.

Referring to FIG. 3, the guide groove 52 has the space 80 for the nut 62. The space 80 has a recess 78 that fits to the nut 62 so as to prevent the nut 62 from slipping off the guide groove 52.

The bolt 60 is passed through the hole 64 of the planar link 56 and coupled to the nut 62. The nut 62 is loosely joined with the bolt 60 so that the heat of the bolt 60 is spaced apart from the planar link 56. The nut 62 loosely coupled with the bolt 60 is inserted into the space 80 of the guide groove 52, and the bolt 60 is tightly joined with respect to the nut 62. Since the nut 62 is supported by the recess 78, the planar link 56 is pulled closer to the nut 62. As a result, the planar link 56 is firmly fixed to a bottom edge region 82 of the heatsink 74.

Since the nut 62 is supported by the recess 78, the nut 62 does not spin in the space 80 as the bolt 60 is tightened. However, in order to perfectly prevent the nut 62 from spinning in the space 80 even when a strong force is applied to tighten up the bolt 60, it is preferable that the width w of the space 80 is determined to correspond to the smallest outer diameter of the nut 62.

As described above, the fixing pin 66 that is inserted into and stands in the slit 58 is elastically supported in the vertical direction by the spring 68. Although the fixing pin 66 is illustrated as being positioned near the outside of the slit 58 in FIG. 3, it will be appreciated that the fixing pint 66 can be moved in the direction indicated by arrow c if required.

FIG. 4 is an inverted perspective view of the heatsink device for cooling a chipset according to the embodiment of the present invention. Referring to FIG. 4, one end of the planar link 56 is supported with respect to the heatsink 74 by the bolt 60. The bolt 60 is movable rectilinearly in the lengthwise direction of the guide groove 52, and the planar link 56 is pivotable about the bolt 60. Therefore, even when the position of installation holes (24 in FIG. 5) in a printed circuit board (C in FIG. 5) does not match the position of the fixing pin 66, the position of the fixing pin 66 can be adjusted to place it directly above the installation hole. FIG. 4 also shows that the bottom 72 of the heatsink 74 that contacts a chipset is processed to be flat.

FIG. 5 illustrates the installation of the heatsink device for cooling a chipset according to the embodiment of the present invention on a printed circuit board. Referring to FIG. 5, two installation holes 24, into which the fixing pins 66 are inserted, are formed near a chipset A through a printed circuit board C.

In this embodiment, since two installation holes 24 are formed at diagonally opposing positions near the chipset A, two planar links 56 are fixed at corresponding diagonally opposing positions on the bottom of the heatsink 74, and the fixing pins 66 in the slits 58 are positioned directly above the corresponding installation holes 24. Next, the heatsink 74 to which the installation units 54 are attached are placed on the top surface of the chip A, and the fixing pins 66 are pressed to couple to the installation holes 24. As result, the heasink 74 is mounted on the printed circuit board C, as shown in FIG. 6. As is appreciated, the bottom of the heatsink 74 elastically contacts the top surface of the chipset A.

FIG. 6 is a sectional view of the heatsink device according to the embodiment of the present invention mounted on the printed circuit board. As shown in FIG. 6, a portion of each planar link 56 is fixed to a bottom edge region 82 of the heatsink 74. This binding structure which binds the planar link 56 to the heatsink 74 is achieved by tightening the bolt 60 with respect to the nut 62. The fixing pin 66 is inserted into the slit 58 (see FIG. 2) of the planar link 56 and pushed into the installation hole 24 so that the flanged conical end 70 protrudes out from the installation hole 24. As described above, since the fixing pin 66 is elastically supported in the vertical direction by the spring 68, the flanged conical end 70 supports the printed circuit board C at the bottom thereof in the vertical direction. In other words, the heatsink 74 is elastically bound to the chipset A.

As described above, since the heatsink 74 is elastically bound to the chipset A using the spring 68, external vibrations or impacts can be absorbed by the spring 68 before acting on the chipset A.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A heatsink device for cooling a chipset mounted on a printed circuit board to interface a central processing unit with a peripheral device, the printed circuit board including a plurality of installation holes near the chipset, the heatsink device comprising:
a heatsink mounted to contact the top surface of the chipset to externally dissipate heat generated by the chipset, the heatsink having a pair of parallel guide grooves at the bottom edge regions which do not contact the chipset; and
an installation unit which is fixed to be movable in each of the guide grooves and is connected to one installation hole of the printed circuit board, to bring the heatsink in contact with the top surface of the heatsink.

2. The heatsink device of claim 1, wherein the installation unit comprises:
a planar link of a predetermined width and length and having a slit extending in a lengthwise direction;
a fixing pin inserted into the slit of the planar link and having a head and a flanged conical end which is inserted through an installation hole of the printed circuit board and supports the printed circuit board upward by the flanged conical end;
a spring slid over the fixing pin to elastically support the head of the fixing pin in the vertical direction while being supported by the rim of the slit of the planar link; and
a link fixing element which fixes one end of the planar link at a desired position in each of the guide grooves.

3. The heatsink device of claim 2, wherein the link fixing element comprises:
a bolt passed through the planar link;
a nut coupled to the bolt, and
each of the guide grooves has a space with a recess fit to support the nut, wherein, while the nut is loosely joined with the bolt and inserted into the space, the bolt is tightened up with respect to the nut such that the planar link is supported by a head of the bolt, so that the planar link is fixed to the heatsink.

4. The heatsink device of any one of claims 1 through 3, wherein the width and cross section of each of the guide grooves is consistent along the entire length of the guide grooves.
